(19) United States
(12) Patent Application Publication
(10) Pub. No.: US 2024/0224819 A1
(43) Pub. Date: Jul. 4, 2024

(54) SEAMED RESISTIVE RANDOM ACCESS MEMORY CELL

(71) Applicant: INTERNATIONAL BUSINESS MACHINES CORPORATION, ARMONK, NY (US)

(72) Inventors: Chanro Park, Clifton Park, NY (US); Kangguo Cheng, Schenectady, NY (US); Youngseok Kim, Upper Saddle River, NJ (US); Julien Frougier, Albany, NY (US); Ruilong Xie, Niskayuna, NY (US); Takashi Ando, Eastchester, NY (US)

(21) Appl. No.: 18/147,129

(22) Filed: Dec. 28, 2022

(51) Int. Cl. H10N 70/00; H10B 63/00

(52) U.S. Cl. CPC H10N 70/023; H10B 63/80; H10N 70/8416; H10N 70/8833

(57) ABSTRACT

A method of manufacturing a resistive random access memory (RRAM) cell includes forming an electrode, and forming an insulator on the electrode, the insulator having a pore and an insulator surface. The method also includes forming a dielectric material on the insulator and the electrode using an atomic layer deposition (ALD) process such that a seam exists in the dielectric material, and forming another electrode on the dielectric material.

### BACKGROUND

The present invention relates to computer memory, and more specifically, to resistive random access memory devices.

Resistive random access memory (RRAM or ReRAM) can be utilized for both training and inference in analog computing for artificial intelligence. Traditional RRAM cells can include a switching layer comprised of a high dielectric constant (high-K) material. A switching layer can be formed, set, reset, and read by applying various electrical biases across the switching layer. These actions can change the electrical resistance of an RRAM cell that contains the switching layer, which allows the RRAM cell to function as a memory cell. However, the process of setting and resetting can degrade the dielectric material over many cycles, which can decrease the difference between the high resistance state and the low resistance state. The RRAM will fail once the difference is low enough because it will be unreliable to tell the two states apart.

### SUMMARY

According to an embodiment of the present disclosure, a method of manufacturing an RRAM cell includes forming an electrode, and forming an insulator on the electrode, the insulator having a pore and an insulator surface. The method also includes forming a dielectric material on the insulator and the electrode using an atomic layer deposition (ALD) process such that a scam exists in the dielectric material, and forming another electrode on the dielectric material.

According to an embodiment of the present disclosure, an RRAM cell includes an electrode, a dielectric layer formed on the electrode, the dielectric layer being formed using an atomic layer deposition (ALD) process such that a seam exists in the dielectric layer, and another electrode formed on the dielectric layer.

According to an embodiment of the present disclosure, a method of using an RRAM cell includes forming, using a first electrical bias, a filament in a seam in a dielectric layer to electrically connect a first electrode on a first side of the dielectric layer with a second electrode on a second side of the dielectric layer, and applying a second electrical bias that has an opposite polarity to the first electrical bias to eliminate some of the filament to electrically disconnect the first electrode and the second electrode. The method also includes measuring the electrical resistance of the cell to be a first value, applying a third electrical bias that has a same polarity as the first electrical bias to reform the filament to electrically connect the first electrode and the second electrode, and measuring the electrical resistance of the cell to be a second value that is lower than the first value.

### BRIEF DESCRIPTION OF THE DRAWINGS

FIG. 1A is a cross-section view of an RRAM cell, in accordance with an embodiment of the present disclosure.

FIG. 1B is a perspective view of a seam in the RRAM cell of FIG. 1A, in accordance with an embodiment of the present disclosure

FIG. 2 is a cross-section view of the RRAM cell of FIG. 1A including filaments in the seam, in accordance with an embodiment of the present disclosure.

FIG. 3 is a flowchart of a method of manufacturing the RRAM cell of FIG. 1A, in accordance with an embodiment of the present disclosure.

FIGS. 4A-4G are a series of cross-section views of the method of FIG. 3 of manufacturing an alternative RRAM cell, in accordance with an embodiment of the present disclosure.

### DETAILED DESCRIPTION

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layers “C” and “D”) are between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus. In addition, any numerical ranges included herein are inclusive of their boundaries unless explicitly stated otherwise.

For purposes of the description hereinafter, the terms “upper,” “lower,” “right,” “left,” “vertical,” “horizontal,” “top,” “bottom,” and derivatives thereof shall relate to the described structures and methods, as oriented in the drawing Figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition can be any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching can be any process that removes material from the wafer. Examples include etch processes (either wet or dry), chemical mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping can be the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide (SiO₂), silicon nitride (SiN), silicon nitride carbide (SiNC), tetraethyl orthosilicate (TEOS), etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography can be the formation of three-dimensional relief images or patterns on the semiconductor substrate for subsequent transfer of the pattern to the substrate. In semiconductor lithography, the patterns are formed by a light-sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

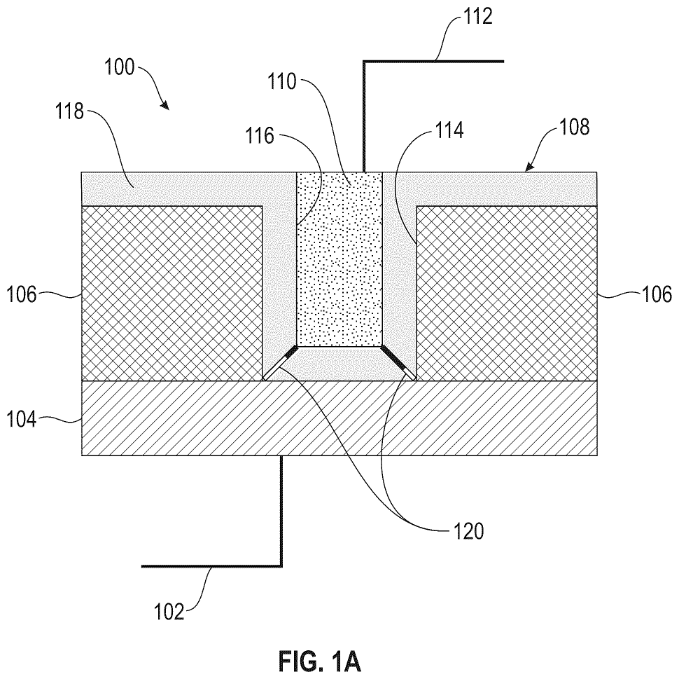

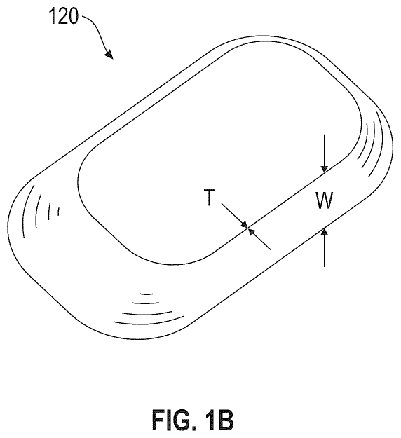

FIG. 1A is a cross-section view of RRAM cell 100 for use in, for example, an IC (not shown). In the illustrated embodiment, RRAM cell 100 comprises bottom wire 102, bottom electrode 104, insulator 106, dielectric layer 108, top electrode 110, and top wire 112.

In the illustrated embodiment, the bottom of bottom electrode 104 is electrically connected to the top of bottom wire 102, which can receive electrical signals from other components (not shown) of the IC. For example, bottom wire 102 can be connected to a transistor (not shown) for a one transistor one resistor (1T1R) structure similar to a dynamic random access memory (DRAM) wherein the transistor acts as a selector device. Alternatively, a diode or ovonic threshold switch (OTS) can be used as the selector device.

In the illustrated embodiment, bottom electrode 104 has a flat shape which is in direct contact with insulator 106. Insulator 106 includes pore 114 that extends through a full height of insulator 106, such that insulator 106 does not cover all of bottom electrode 104. Dielectric layer 108 has cup portion 116 that extends into pore 114 and flange portion 118 that extends across the top of insulator 106, so dielectric layer 108 is in direct contact with the top of insulator 106, the sides of pore 114, and the top of bottom electrode 104. Thereby, insulator 106 can structurally support dielectric layer 108, and dielectric layer 108 can selectively electrically isolate bottom electrode 104 and top electrode 110. Top electrode 110 is in direct contact with the interior of cup portion 116, and the top of top electrode 110 is coplanar with the top of dielectric layer 108. Top electrode 110 is electrically connected to top wire 112, which can deliver electrical signals from RRAM cell 100 to other components (not shown) of the IC.

A cross-section of various components and/or the entirety of RRAM cell 100 (into the page in FIG. 1A) can be rectangular, although in other embodiments, it can be circular, square, oval, or any other suitable shape. In some embodiments, RRAM cells 100 with rectangular shapes have rounded interior edges and/or corners. For example, the pore 114 can be rounded along its vertical sides (e.g., fillets) and where pore 114 meets bottom electrode 104. Similarly, cup portion 116 can have rounded edges where it contacts the vertical sides and bottom of top electrode 110.

In the illustrated embodiment, bottom electrode 104 and top electrode 110 are comprised of a very electrically conductive material, such as metal or metallic compound, for example, titanium nitride (TiN), tungsten (W), tantalum (Ta), tantalum nitride (TaN), copper (Cu), cobalt (Co), and/or silver (Ag). In particular, Cu, Co, and Ag are mobile species in that they can migrate through and along the surfaces of solid materials on an atomic scale. In some embodiments, electrodes 104, 110 can be doped with Cu, Co, and/or Ag if they do not otherwise include Cu, Co, and/or Ag. In some embodiments, electrodes 104, 110 are formed with a thin layer of Cu, Co, and/or Ag that contacts dielectric layer 108 if electrodes 104, 110 do not otherwise include them. In some embodiments, only bottom electrode 104 includes a mobile species, and in other embodiments, only top electrode 110 includes a mobile species.

In the illustrated embodiment, dielectric layer 108 is composed essentially of a transition metal oxide that has two particular qualities: 1) it is a diffusion barrier to a mobile species present in electrodes 104, 110; and 2) it forms a scam at interior edges when deposited by an ALD process (as shown by “seam 120” in FIG. 1B). In some embodiments, dielectric layer 108 is composed essentially of a high dielectric constant (high-K) material, such as, for example, a titanium oxide (e.g., TiO, TiO₂, Ti₂O₃, Ti₃O, Ti₂O, TiₙO₂ₙ₋₁), SiN, a silicon oxide (e.g., SiO₂), hafnium oxide (HfO₂), zirconium dioxide (ZrO₂), and aluminum oxide (Al₂O₃). The terms “composed essentially” and “consist essentially,” as used herein with respect to materials of different layers, indicates that other materials, if present, do not materially alter the basic characteristics of the recited materials. For example, a dielectric layer 108 consisting essentially of a high-K transition metal oxide material does not include other materials that materially alter the basic characteristics of the high-K transition metal oxide material.

FIG. 1B is a perspective view of seam 120 in dielectric layer 108 (shown in FIG. 1A). As alluded to above, dielectric layer 108 is comprised of a material that forms seams where two growing fronts meet. Such growing fronts begin at each face of pore 114 (shown in FIG. 1A) and the area of bottom electrode 104 (shown in FIG. 1A) that is at the bottom of pore 114. Thereby, seam 120 is present where each side and the bottom of cup portion 116 (shown in FIG. 1A) meet.

In the illustrated embodiment, seam 120 is depicted as being a solid object. However, scam 120 is a void in dielectric layer 108. Scam 120 has a ribbon shape that angles inward from the bottom electrode 104/insulator 106 towards top electrode 110 (shown in FIG. 1A). In other words, scam 120 angles in towards a central axis (not shown) of pore 114 as seam extends upwards towards a top surface of insulator 106. The inward lean is due to each side of cup portion 116 being smaller in surface area with each subsequent pass of the ALD process. In some embodiments, seam 120 has thickness T that is less than 2 nanometers (nm), and in some embodiments, thickness T is about 1 nm. In some embodiments, scam 120 has width W that is between 5 nm and 30 nm, and in some embodiments, width W is about 15 nm.

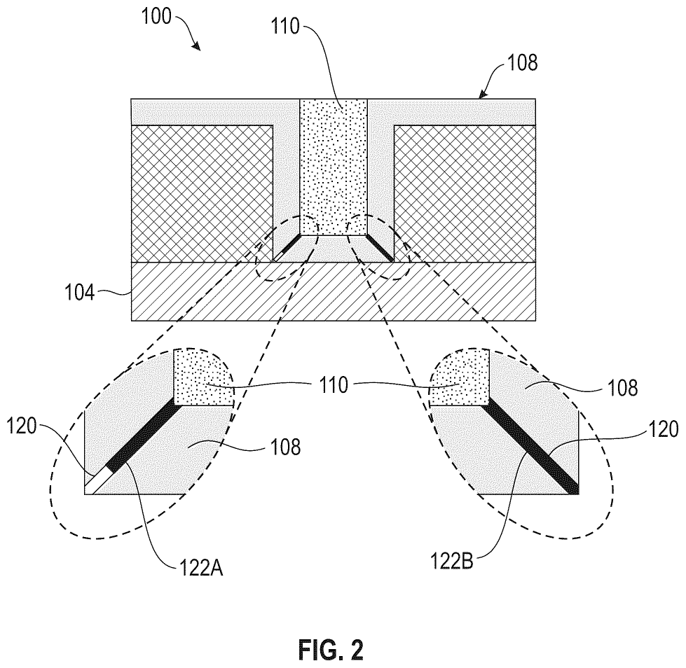

FIG. 2 is a cross-section view of RRAM cell 100 including filaments 122A and 122B (collectively “filaments 122”) in seam 120. In the illustrated embodiment, RRAM cell 100 can be operated as a memory cell by first forming filaments 122 through seam 120 in dielectric layer 108. Filaments 122 can be formed by applying a relatively large voltage across dielectric layer 108 (i.e., causing an electrical bias between bottom electrode 104 and top electrode 110). Filaments 122 are formed in scam 120 by metal atoms from bottom electrode 104 or top electrode 110 being forced into seam 120 by the electrical bias. In some embodiments, the mobile species present in bottom electrode 104 or top electrode 110 make up some or essentially all of filaments 122. Filaments 122 form in scam 120 because dielectric layer 108 is a diffusion barrier for the mobile species, as well as being a diffusion barrier for the other metal materials in electrodes 104, 110. In some embodiments, there are many (e.g., ten) filaments 122, although only two have been shown for the sake of simplicity. Filaments 122 may tend to form more extensively (e.g., further through scam 120 and/or more frequently along seam 120) at certain points in seam 120, for example, where scam 120 is thicker and influx of the mobile species is easier. Because filaments 122 are metallic, filaments 122 are pathways of low electrical resistance within dielectric layer 108. Filaments 122 will grow from one electrode towards the other depending on the polarity, where, in FIG. 2, filaments 122 are shown as growing from top electrode 110 towards bottom electrode 104.

In the absence of filaments 122, there is a relatively high electrical resistance through dielectric layer 108. However, a single (or multiple) filament 122 (in this example, filament 122B, but not filament 122A) extends all the way across dielectric layer 108 such that it is in direct contact with and electrically connected to both bottom electrode 104 and top electrode 110. Because filament 122B is an electrically conductive pathway through dielectric layer 108, dielectric layer 108 goes from having a relatively high electrical resistance to having a relatively low electrical resistance. This difference in the electrical resistance across dielectric layer 108 leads to substantial difference in the electrical resistance across RRAM cell 100 (i.e., between bottom wire 102 and top wire 112). The initial growth of filaments 122 is known as “forming” and can be performed, for example, using a relatively high voltage in the 2 volt (V) to 3 V range.

Once filament 122B is formed, it can be controlled with relatively moderate voltages/electrical biases across dielectric layer 108. For example, if the polarity of the electrical bias is opposite to that of the forming voltage difference, then filaments 122 (including filament 122B) will recede. This can undo the (electrical and physical) bridging that filament 122B previously performed between bottom electrode 104 and top electrode 110. At that point, the electrical resistance across dielectric layer 108 would change to a relatively high value, as would the electrical resistance across RRAM cell 100. The reduction of filaments 122 that breaks the connection of filament 122B to top electrode 110 is known as “resetting” or “erasing”, and RRAM cell 100 is considered to be “off”. Resetting RRAM cell 100 can be performed, for example, using a relatively moderate voltage in the (−)0.5 V to (−)1 V range.

On the other hand, if the polarity of the electrical bias is subsequently switched to be the same as that of the forming voltage difference, then filaments 122 (including filament 122B) will grow again. This can allow filament 122B (or another one of filaments 122) to grow all the way across dielectric layer 108, rejoining bottom electrode 104 and top electrode 110 with a relatively low electrical resistance pathway. At that point, the electrical resistance across dielectric layer 108 would change to a relatively low value, as would the electrical resistance across RRAM cell 100. The growth of filaments 122 that makes the connection of filament 122B to top electrode 110 is known as “setting” or “writing”, and RRAM cell 100 is considered to be “on”. Setting RRAM cell 100 can be performed, for example, using a relatively moderate voltage in the 0.5 V to 1 V range.

To read the data stored in RRAM cell 100, a relatively low voltage that is less than 0.5 V can be applied across RRAM cell 100 so that its electrical resistance can be measured. If the reading is relatively low, then RRAM cell 100 is “on”, but if the reading is relatively high, then RRAM cell is “off”. Once filament 122B is set, in some embodiments, the electrical resistance of RRAM cell 100 is around 100 kiloohms (kΩ) to 3 megaohms (MΩ). On the other hand, once filament 122B is reset, the electrical resistance of RRAM cell 100 is around 1 kΩ to 3 kΩ (e.g., around one hundred to three thousand ten times less than when filament 122B is set). The current through dielectric layer 108, when filament 122B is set, can be manipulated by the drain current of its corresponding transistor. The forming, setting, resetting, and reading voltages and resistances provided above are merely from one exemplary embodiment. In other embodiments, these values can be different, for example, depending on the concentration of mobile species in top electrode 110.

The components and configuration of RRAM cell 100 provide a diffusing barrier (e.g., dielectric layer 108) with open space (e.g., scam 120) for forming electrical connections (e.g., filaments 122) between poles (e.g., electrodes 104, 110). This can increase the lifespan of RRAM 100 (e.g., beyond 1 billion cycles of setting/resetting) and decrease the initial forming energy (which can eliminate the need for special forming circuitry in the IC). In addition, the repeatability of RRAM 100 is improved compared to traditional RRAM cells. This is because traditional RRAM cells have a switching layer instead of a diffusion barrier layer. In such switching layers, the filaments form randomly within the bulk of the switching layer since there are no preferred paths between the electrodes. That greatly increases the number of filaments that are growing during formation, which requires more energy. Also, the switching layer itself can be degraded from the cycling. For example, the filaments can thicken as they are built up, but when they reduce, they can remain slightly larger than before the cycle started. This can cause the distance between the end of the filament and the corresponding electrode to narrow with more cycles, which decreases the electrical resistance when the cell is off and degrades the function of the RRAM cell.

However, because seam 120 has a fixed thickness, dielectric layer 108 prevents filaments 122 from thickening all around their circumferences (i.e., filaments can only thicken side-to-side within seam 120). This slows the degradation process compared to traditional RRAM cells that have filaments that can thicken in every direction since they form in the bulk of the switching layer. Furthermore, the properties of RRAM cell 100 can exist without requiring the use of an epitaxial layer. Thereby, RRAM cell 100 can exist in the back end of line (BEOL) of an IC.

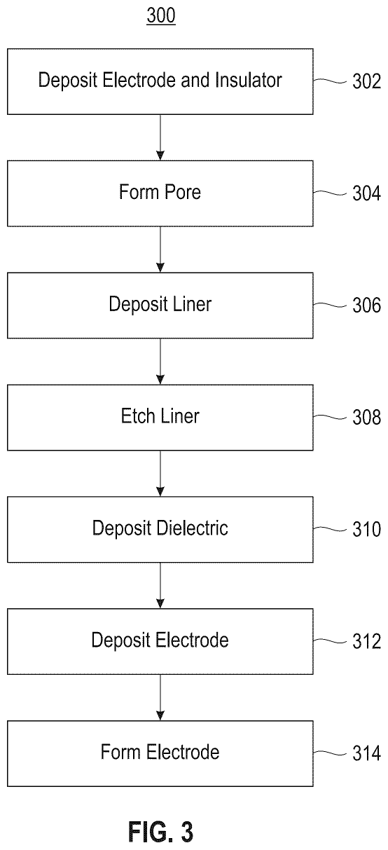

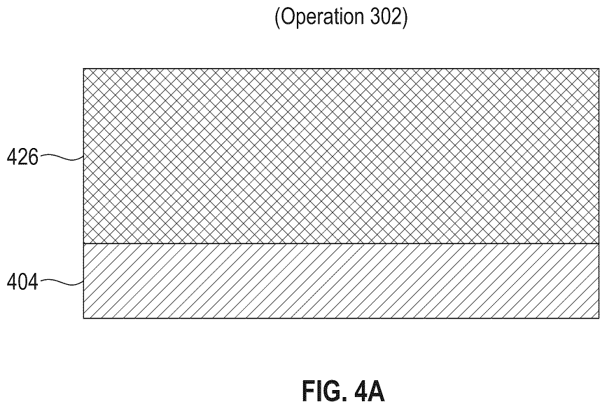

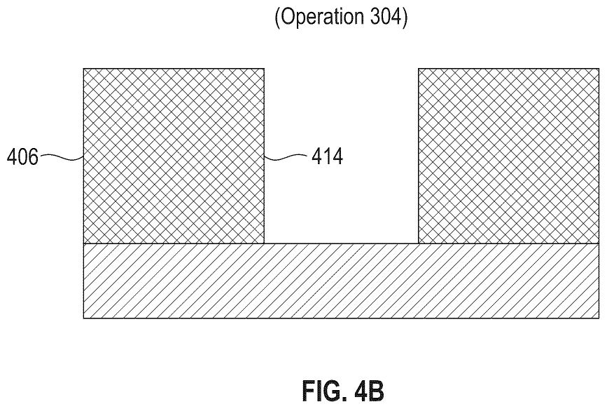

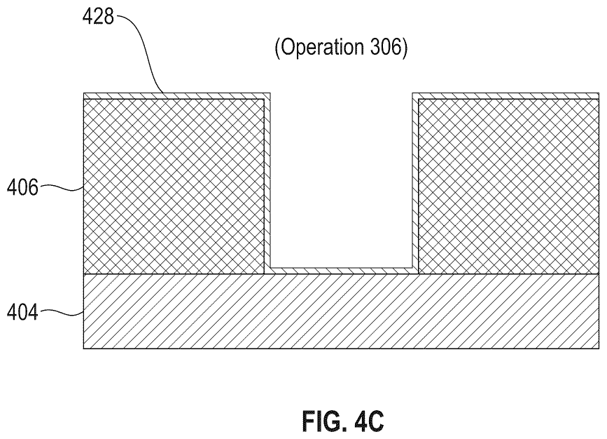

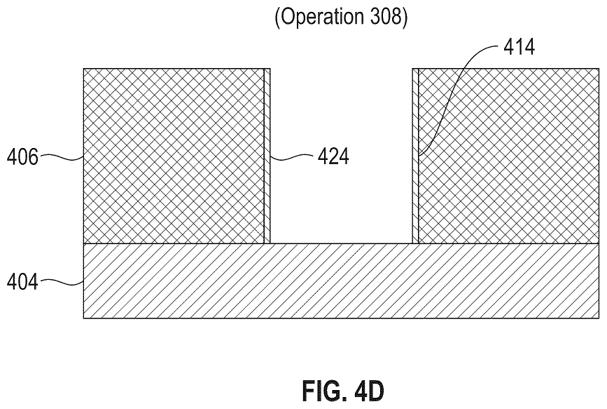

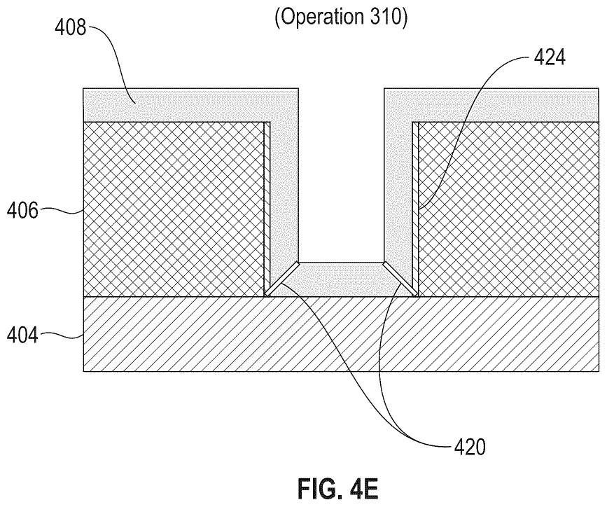

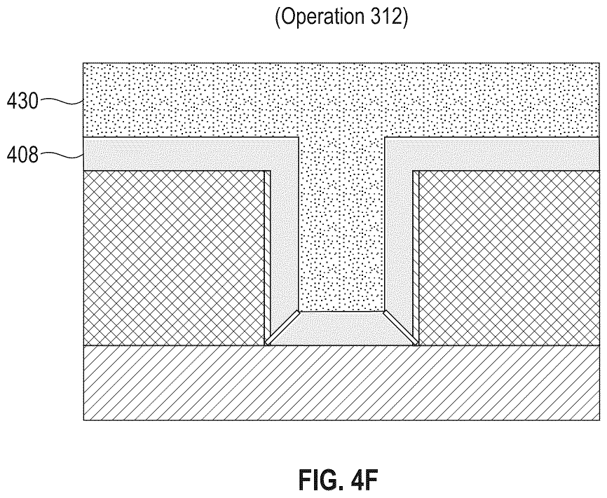

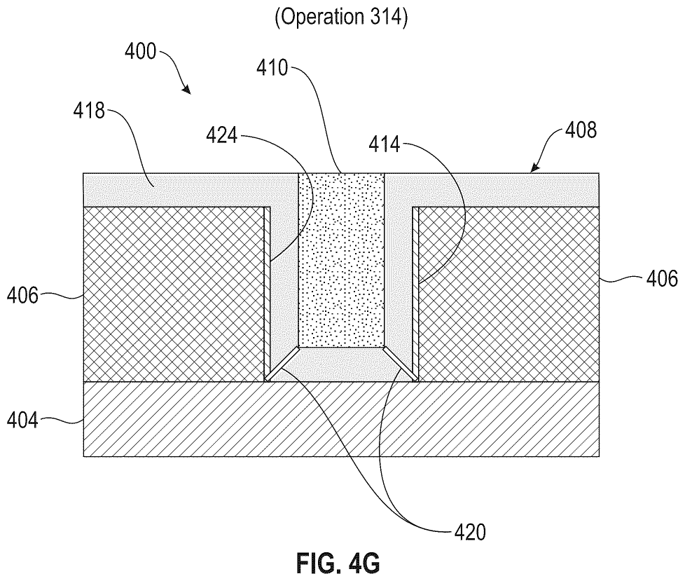

FIG. 3 is a flowchart of method 300 of manufacturing alternative RRAM cell 400. FIGS. 4A-4G are a series of views of method 300 of manufacturing RRAM cell 400. FIGS. 3 and 4A-4G will now be discussed in conjunction with one another wherein each operation of method 300 is illustrated by one of FIGS. 4A-4G. In addition, RRAM cell 400 shares features with RRAM cell 100 (shown in FIG. 2), and where elements are similar or the same, the reference numeral will be three hundred higher than the corresponding element. However, there are some differences, for example, liner 424 which is a diffusion barrier to prevent mobile species from top electrode 410 from penetrating into insulator 406. Liner 424 can be comprised of, for example. Ta. TaN, cobalt (Co), and/or ruthenium (Ru).

During the discussion of method 300, references may be made to features of RRAM cell 400 that are shown in FIG. 4G (among other places). In the illustrated embodiment, method 300 starts at operation 302, wherein bottom electrode 404 and insulator material 426 are deposited. At operation 304, pore 414 is formed in insulator material 426 to form insulator 406. At operation 306, liner material 428 is deposited on bottom electrode 404 and insulator 406. At operation 308, the upward facing surfaces of liner material 428 are removed to form liner 424, which covers the sides of pore 414 but exposes the top of insulator 406 and part of bottom electrode 404.

In the illustrated embodiment, at operation 310, dielectric layer 408 is formed on insulator 406, bottom electrode 404, and liner 424. Dielectric layer 408 is formed using an ALD process such that seam 420 is present when dielectric layer 408 is finished. At operation 312, electrode material 430 is formed on dielectric layer 408, and then electrode material 430 can be doped with a mobile species if desired. In some embodiments, operation 312 occurs by depositing a thin layer of mobile species first, and the remainder of electrode material 430 second. While electrode material 430 is deposited on seam 420, there is insufficient motivational force to cause the mobile species to migrate into seam 420. However, top electrode 110 (e.g., the mobile species therein) is configured to migrate into seam 420 in response to an appropriate electrical bias being applied. At operation 314, electrode material 430 is planarized to expose the top of dielectric layer 408 and form top electrode 410 and complete RRAM cell 400. In some embodiments, flange portion 418 of dielectric layer 408 is also removed to expose the top of insulator 406.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of manufacturing a resistive random access memory (RRAM) cell, the method comprising:
forming a first electrode;
forming an insulator on the first electrode, the insulator having a pore and an insulator surface;
forming a dielectric material on the insulator and the first electrode using an atomic layer deposition (ALD) process such that a seam exists in the dielectric material; and
forming a second electrode on the dielectric material.

2. The method of claim 1, further comprising forming an electrically conductive filament in the seam that electrically connects the first electrode and the second electrode.

3. The method of claim 1, wherein the second electrode comprises a mobile species of metal.

4. The method of claim 3, wherein the mobile species of metal is doped into the second electrode after the second electrode is formed.

5. The method of claim 3, wherein the mobile species of metal is formed on the dielectric material prior to forming a remainder of the second electrode on the mobile species of metal.

6. The method of claim 3, wherein the mobile species of metal is silver, cobalt, and/or copper.

7. The method of claim 1, wherein the dielectric material is selected from the group consisting of titanium oxide, silicon nitride, silicon oxide, hafnium oxide, zirconium dioxide, and aluminum oxide.

8. The method of claim 1, further comprising forming a liner in the pore prior to forming the dielectric material.

9. The method of claim 8, wherein the liner is comprised of material selected from the group consisting of tantalum, tantalum nitride, cobalt, and ruthenium.

10. The method of claim 1, further comprising removing some of the dielectric material and some of the second electrode to expose the insulator surface.

11. A resistive random access memory (RRAM) cell comprising:
a first electrode;
a dielectric layer formed on the first electrode, the dielectric layer being formed using an atomic layer deposition (ALD) process such that a seam exists in the dielectric layer; and
a second electrode formed on the dielectric layer.

12. The RRAM cell of claim 11, further comprising an electrically conductive filament in the seam that electrically connects the first electrode and the second electrode.

13. The RRAM cell of claim 11, wherein the second electrode comprises a mobile species of metal.

14. The RRAM cell of claim 13, wherein the mobile species of metal is doped into the second electrode after the second electrode is formed.

15. The RRAM cell of claim 13, wherein the mobile species of metal is a first layer of the second electrode that is closest to the dielectric layer.

16. The RRAM cell of claim 13, wherein the mobile species of metal is silver, cobalt, and/or copper.

17. The RRAM cell of claim 11, wherein the dielectric material is selected from the group consisting of titanium oxide, silicon nitride, silicon oxide, hafnium oxide, zirconium dioxide, and aluminum oxide.

18. The RRAM cell of claim 11, further comprising:
an insulator positioned between the first electrode and the dielectric layer; and
a liner positioned between the insulator and the dielectric layer.

19. The RRAM cell of claim 18, wherein the liner is comprised of material selected from the group consisting of tantalum, tantalum nitride, cobalt, and ruthenium.

20. A method of using a resistive random access memory (RRAM) cell, the method comprising:
forming, using a first electrical bias, a filament in a seam in a dielectric layer to electrically connect a first electrode on a first side of the dielectric layer with a second electrode on a second side of the dielectric layer;
applying a second electrical bias that has an opposite polarity to the first electrical bias to eliminate some of the filament to electrically disconnect the first electrode and the second electrode;
measuring the electrical resistance of the cell to be a first value;
applying a third electrical bias that has a same polarity as the first electrical bias to reform the filament to electrically connect the first electrode and the second electrode; and
measuring the electrical resistance of the cell to be a second value that is lower than the first value.
